(19) United States
(12) Patent Application Publication
(10) Pub. No.: US 2017/0271499 A1
(43) Pub. Date: Sep. 21, 2017

(54) THERMAL-AWARE FINFET DESIGN

(71) Applicant: QUALCOMM Incorporated, San Diego, CA (US)

(72) Inventor: Yong Ju LEE, San Diego, CA (US)

(21) Appl. No.: 15/073,560

(22) Filed: Mar. 17, 2016

(51) Int. Cl. H01L 29/78; H01L 29/10; H01L 29/66; H01L 21/02; H01L 29/20; H01L 29/06; H01L 23/367; H01L 23/373; H01L 29/16

(52) U.S. Cl. CPC H01L 29/785; H01L 23/3731; H01L 29/1033; H01L 29/66795; H01L 29/16; H01L 29/20; H01L 29/0673; H01L 23/367; H01L 21/02488; H01L 21/02532; H01L 21/02546; H01L 21/0254; H01L 29/2003; H01L 21/02178; H01L 21/02175; H01L 29/1606; H01L 21/02527

(57) ABSTRACT

According to various aspects, a thermal-aware finned field-effect transistor (FinFET) may have a design that can substantially reduce hot spot temperatures and resolve other self-heating problems. More particularly, the FinFET design may use aluminum nitride (AlN) fins that can provide a main thermal exit and a source, drain, and channel formed from materials that can spread or dissipate heat, wherein AlN has a high thermal conductivity compared to silicon such that using AlN to form the fins may substantially increase heat flux to a silicon substrate relative to silicon fins. Furthermore, thermal-efficient materials may be used to form the source, drain, and channel structures to further spread heat and decrease hot spot temperatures.

### TECHNICAL FIELD

The various aspects and embodiments described herein generally relate to thermal-aware finned field-effect transistor (FinFET) designs to substantially reduce hot spot temperatures and resolve other FinFET self-heating problems.

### BACKGROUND

A finned field effect transistor (FinFET) generally refers to a non-planar, multi-gate transistor that includes a fin-shaped channel region. For example, FIG. 1 illustrates an exemplary FinFET 10 built on a silicon (Si) substrate 12. As shown in FIG. 1, the FinFET 10 may include an insulator layer 14 (e.g., a silicon dioxide (SiO2) layer) disposed over the Si substrate 12, wherein a source 16, a drain 18, and a channel region 22 may be formed through the insulator layer 14. Furthermore, a gate structure 20 wraps around the channel region 22, wherein the fin length under the gate structure 20, measured in the direction from the source 16 to the drain 18, determines the effective length associated with the channel region 22. Accordingly, due to the low impurity concentration in the fin, less scattering occurs in the channel region 22 when the FinFET 10 is active, thereby improving carrier mobility and offering high current drive. Furthermore, because the gate structure 20 wraps around the channel region 22, the gate structure 20 has excellent control over the conducting channel region 22, which can suppress leakage current (e.g., when the FinFET 10 is off), reduce short-channel effects, and allow lower threshold voltages that can further improve switching speeds and power. Nonetheless, despite providing promising electrostatic characteristics, FinFETs and other nanoscale devices pose non-trivial self-heating challenges.

For example, FIG. 2 illustrates exemplary results from a thermal simulation in a ten (10) nanometer FinFET 10. In particular, as shown therein, applying a bias between the source 16 and the drain 18 causes increases in temperature along the fin 22 disposed in the channel region, which reaches a maximum in the area near the drain 18, as depicted at element 30 (e.g., electrons accelerate when flowing from the source 16 to the drain 18, whereby the temperature due to electron bombardment reaches a maximum near the drain 18). In the simulation results, the temperature at the hot spot 30 was approximately 383K (at 10 W/mK), which is close to the ˜393K maximum operating temperature of digital circuits. As such, the temperature at the hot spot 30 should ideally be less than ˜368K, which is the approximate reliability limit of logic devices.

In that sense, FIG. 3 illustrates exemplary scientific principles to demonstrate the relationship between thermal conductivity and silicon layer thickness that can lead to FinFET self-heating problems based on power consumption and increases in temperature. For example, assuming a current (I) and a resistance (R), a change in voltage may result as defined in Ohm's law, as depicted at 42, and power (P) may also be consumed as a function of the current (I) squared and resistance (R), as depicted at 44. Furthermore, all materials generally have a thermal resistance (Rₜₕ), which can be multiplied by the power consumption (P) to calculate temperature increase, as depicted at 46, and the resulting resistance is a function of the temperature increase, as depicted at 48. As such, based on the principle that all materials have a thermal resistance (Rₜₕ)=1/thermal conductivity, the graph depicted at element 50 shows a relationship between thermal conductivity and silicon layer thickness. For example, a wide silicon layer has a high thermal conductivity, as depicted at element 52, while thermal conductivity may substantially decrease as silicon layer thickness decreases, approaching zero for a 10 nm thick silicon layer, as depicted at element 54. Accordingly, because most photons that are generated in the Joule heating that occurs as electrons accelerate from the source to the drain are confined within the Si fins, continuous scaling can lead to self-heating problems in FinFET devices as silicon-based devices become smaller and smaller.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

According to various aspects, a thermal-aware finned field-effect transistor (FinFET) may have a design that can substantially reduce hot spot temperatures and resolve other self-heating problems that may arise in FinFET devices and other nanoscale devices. More particularly, the FinFET design may use aluminum nitride (AlN) fins that can provide a main thermal exit and a source, drain, and channel formed from materials that can spread or dissipate heat. For example, AlN has a high thermal conductivity compared to silicon (e.g., 285 W/mK versus 5-20 W/mK at a ten (10) nanometer width), whereby using AlN to form the fins may substantially increase heat flux to a silicon substrate relative to silicon fins. Furthermore, thermal-efficient materials may be used to form the source, drain, and channel structures to further spread heat and decrease hot spot temperatures. More particularly, an AlN layer may be deposited over an entire substrate surface and then etched or otherwise patterned to form the AlN fins. Graphene can then be used to form a layer over the AlN layer (including the AlN fins) and an insulator layer that comprises a combined buffer layer and high-k dielectric may be formed over the graphene layer. Accordingly, because AlN has a high thermal conductivity, using AlN as the fin material and having the AlN layer disposed over the entire top surface of the substrate may provide a main thermal exit whereby heat flows from the AlN layer downward into the substrate. Furthermore, graphene also has a high thermal conductivity (˜500-2000 W/mK), whereby the graphene layer disposed between the AlN layer and the insulator layer may also play an important role to spread heat and decrease hot spot temperatures. Accordingly, whereas a conventional FinFET has fins formed from silicon (Si), which has a relatively low thermal conductivity at nanoscale widths, using AlN (which has a substantially higher thermal conductivity at the same width) in the thermal-aware FinFET may advantageously result in faster phonon and heat transport to the substrate. Furthermore, graphene has a much higher thermal conductivity than silicon, silicon carbide (SiC), silicon-germanium (SiGe), and/or other silicon-based materials that are typically used in a FinFET source and drain stack, whereby using graphene in the source and drain stack may advantageously aid in quickly spreading heat from high to low temperatures.

According to various aspects, a finned field-effect transistor (FinFET) having a thermal-aware design may comprise a source stack formed on a substrate, a drain stack formed on the substrate, and a gate stack formed on the substrate in a channel region disposed between the source stack and the drain stack. In particular, the gate stack may comprise multiple channel structures intersecting the source stack and the drain stack and thermal-efficient layers formed around the multiple channel structures, wherein the thermal-efficient layers may be formed from a high-k dielectric material and a material having a high thermal conductivity. Furthermore, in various embodiments, the multiple channel structures may be formed from a material having a lattice matched to the material in the thermal-efficient layers having the high thermal conductivity such that the thermal-efficient layers and the multiple channel structures can be formed over one another in a generally interleaved manner through epitaxial growth. For example, in various embodiments, the material used in the thermal-efficient layers may comprise aluminum nitride (AlN), beryllium oxide (BeO), etc. and the material used in the channel structures with the matching lattice structure may comprise silicon, indium gallium arsenide, silicon-germanium, a III-V nitride, etc. As such, the material having the high thermal conductivity may cause heat to flow downward into the substrate and upward to a metal gate formed atop the gate stack, while the multiple channel structures intersecting the source stack and the drain stack may spread heat from the gate stack into the source stack and the drain stack, which may be formed from materials that cause the heat to further flow downward into the substrate and upward through the source stack and the drain stack.

According to various aspects, a method for forming a FinFET having the thermal-aware design described above may comprise forming a source stack and a drain stack on a substrate and forming a gate stack on the substrate in a channel region disposed between the source stack and the drain stack, wherein forming the gate stack may comprise forming multiple channel structures that intersect the source stack and the drain stack and forming thermal-efficient layers around the multiple channel structures from a high-k dielectric material and a material having a high thermal conductivity.

According to various aspects, a finned field-effect transistor (FinFET) having a thermal-aware design may comprise a substrate, a source stack and a drain stack that each comprise an aluminum nitride (AlN) layer formed on the substrate and a graphene layer formed over the AlN layer and a gate stack formed on the substrate, wherein the gate stack may comprise one or more fin-shaped structures formed from AlN in a channel region between the source stack and the drain stack and a graphene channel formed over the fin-shaped structures. As such, the AlN layer and the one or more fin-shaped structures formed from AlN may cause heat to flow downward into the substrate. Furthermore, the graphene layer may substantially surround the AlN layer and extend through the gate stack to form the graphene channel such that the graphene channel may substantially surround the AlN fin-shaped structures formed in the channel region, whereby the graphene layer and the graphene channel may spread heat throughout the thermal-aware FinFET.

According to various aspects, a method for forming a FinFET having the thermal-aware design described above may comprise forming a source stack and a drain stack on a substrate, wherein the source stack and the drain stack may each comprise an aluminum nitride (AlN) layer formed on the substrate and a graphene layer formed over the AlN layer, and forming a gate stack on the substrate, wherein forming the gate stack AlN may comprise forming one or more fin-shaped structures from AlN in a channel region between the source stack and the drain stack and forming a graphene channel over the fin-shaped structures.

Other objects and advantages associated with the aspects and embodiments disclosed herein will be apparent to those skilled in the art based on the accompanying drawings and detailed description.

### BRIEF DESCRIPTION OF THE DRAWINGS

A more complete appreciation of the various aspects and embodiments described herein and many attendant advantages thereof will be readily obtained as the same becomes better understood by reference to the following detailed description when considered in connection with the accompanying drawings which are presented solely for illustration and not limitation, and in which:

FIG. 1 illustrates an exemplary finned field-effect transistor (FinFET), according to various aspects.

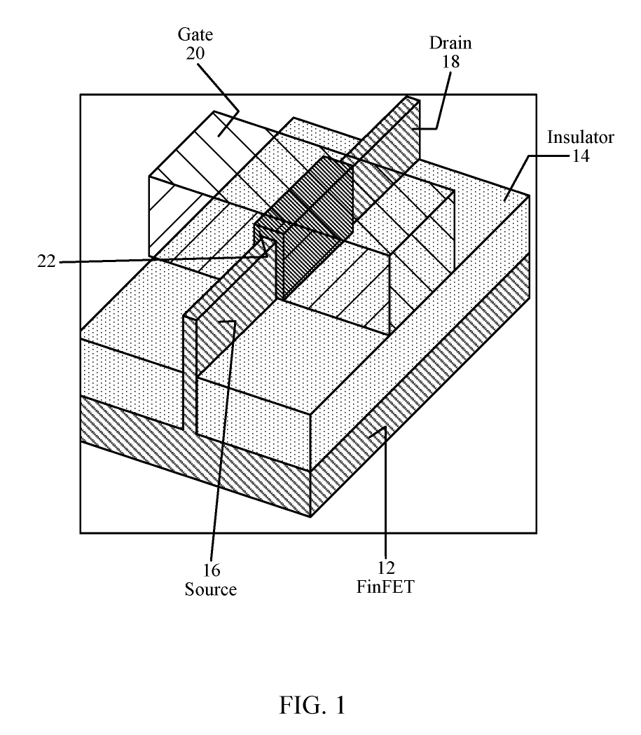

FIG. 2 illustrates an exemplary ten (10) nanometer FinFET with a simulated hot spot temperature that exceeds the approximate reliability limit of logic devices, according to various aspects.

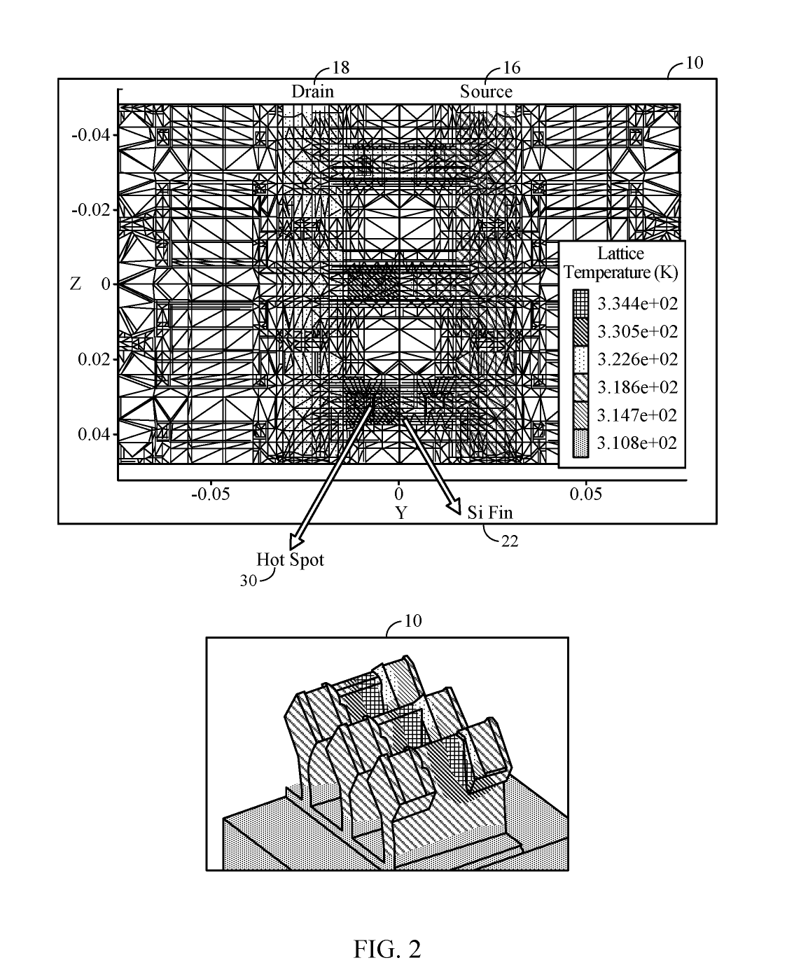

FIG. 3 illustrates exemplary scientific principles to demonstrate the relationship between thermal conductivity and silicon layer thickness that can lead to FinFET self-heating problems, according to various aspects.

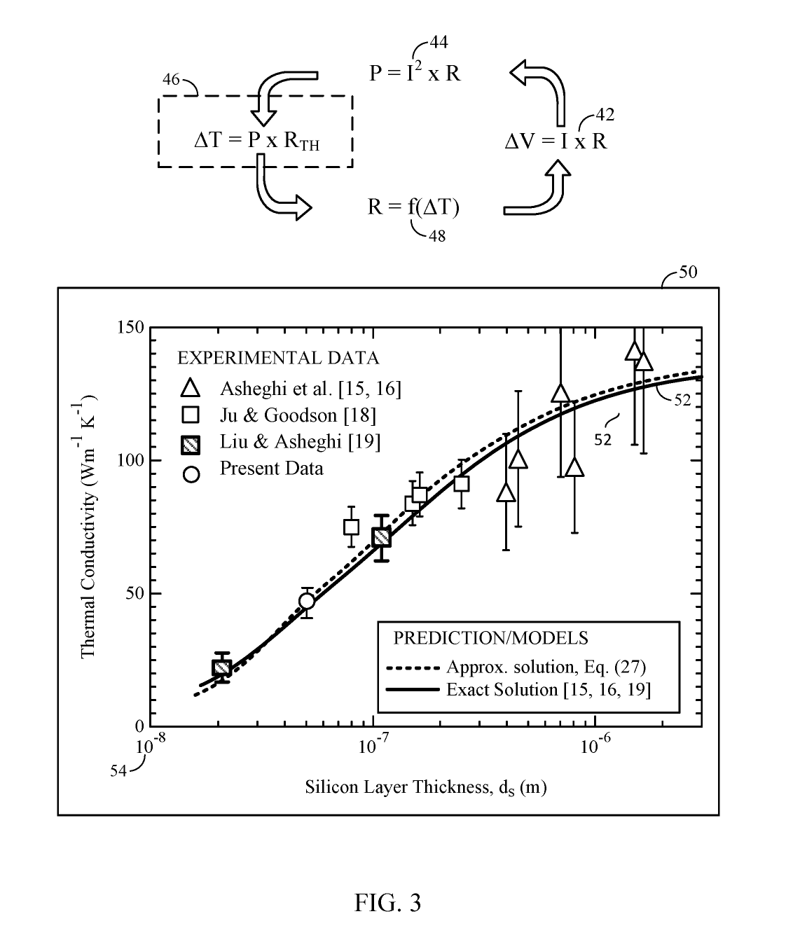

FIG. 4A and FIG. 4B illustrate exemplary FinFET layouts having a thermal-aware design to address FinFET self-heating problems, according to various aspects.

FIG. 5A illustrates an exemplary gate cut that may result in a horizontal thermal-aware FinFET as shown in FIG. 5B, according to various aspects.

FIG. 6A and FIG. 6B illustrate an exemplary vertical FET with multiple fingers based on the FinFET layouts shown in FIG. 4A-4B, according to various aspects.

FIG. 7 illustrates exemplary atomic structures that can be used to form thermal-efficient device structures to be used in the thermal-aware FinFET design(s) described herein through epitaxial growth, according to various aspects.

FIG. 8 illustrates an exemplary comparison between a horizontal FinFET and a multi-finger vertical FET that are each based on the thermal-aware FinFET design described herein, according to various aspects.

FIG. 9 illustrates an exemplary method to form a horizontal FinFET and/or a multi-finger vertical FET based on the thermal-aware FinFET design described herein, according to various aspects.

FIG. 10 illustrates an exemplary processor-based system that may comprise one or more integrated circuits that implement the thermal-aware FinFET design(s) described herein, according to various aspects.

### DETAILED DESCRIPTION

Various aspects and embodiments are disclosed in the following description and related drawings to show specific examples relating to exemplary aspects and embodiments. Alternate aspects and embodiments will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and embodiments disclosed herein.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein describes particular embodiments only and should not be construed to limit any embodiments disclosed herein. As used herein, the singular forms “a,” “an,” and “the” are intended to include the plural forms as well, unless the context clearly indicates otherwise. Those skilled in the art will further understand that the terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

Further, various aspects and/or embodiments may be described in terms of sequences of actions to be performed by, for example, elements of a computing device. Those skilled in the art will recognize that various actions described herein can be performed by specific circuits (e.g., an application specific integrated circuit (ASIC)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects described herein may be embodied in a number of different forms, all of which have been contemplated to be within the scope of the claimed subject matter. In addition, for each of the aspects described herein, the corresponding form of any such aspects may be described herein as, for example, “logic configured to” and/or other structural components configured to perform the described action.

According to various aspects, as described in further detail herein, a thermal-aware finned field-effect transistor (FinFET) design may address self-heating problems in FinFET devices and other nanoscale devices. More particularly, in various embodiments, a FinFET layout may comprise aluminum nitride (AlN) fins that can provide a main thermal exit and a source, drain, and channel formed from materials that can spread or dissipate heat. For example, AlN has a high thermal conductivity (K=285 W/mK) compared to a silicon (Si) fin with a ten (10) nanometer width (5-20 W/mK), whereby using AlN to form the fins in the thermal-aware FinFET design may increase heat flux to a silicon substrate ˜15-60 times relative to fins formed from silicon. Furthermore, using thermal-efficient materials to form the source, drain, and channel device structures may further spread heat and decrease hot spot temperatures.

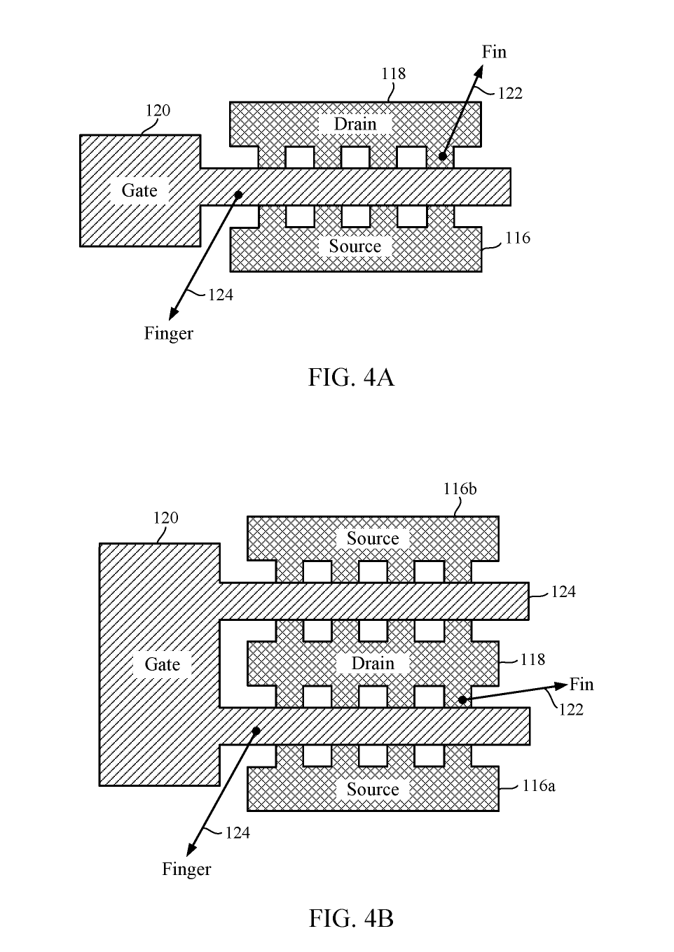

According to various aspects, referring to FIG. 4A and FIG. 4B, the example thermal-aware FinFET layouts illustrated therein may have a design that can address FinFET self-heating problems. More particularly, FIG. 4A illustrates a top-down view of a thermal-aware FinFET layout that comprises a source 116, a drain 118, and various fins 122 disposed in a channel region between the source 116 and the drain 118.

Furthermore, a gate stack 120 may include a finger 124 wrapping the fins 122 disposed in the channel region. Furthermore, FIG. 4B illustrates a top-down view of another thermal-aware FinFET layout that comprises a drain 118 disposed between a first source 116a and a second source 116 and various fins 122 disposed in a channel region between the drain 118 and the first source 116a and a channel region between the drain 118 and the second source 116b. In FIG. 4b, the gate stack 120 may include two fingers 124 wrapping the fins 122 disposed in the channel regions between the drain 118 and the sources 116a, 116b. In general, whether a device implements the FinFET layout shown in FIG. 4A or FIG. 4B may depend on the particular application. For example, a low-speed application may have less demanding performance requirements, whereby using a layout with fewer fins as shown in FIG. 4A may be used. On the other hand, more fingers and/or fins may provide improved performance such that the layout shown in FIG. 4B may be used in a smartphone with substantial performance demands In either case, as will be described in further detail herein, the source(s) 116, the drain 118, the fins 122, and the gate stack 120 (including the fingers 124) may be formed from materials chosen to efficiently spread or otherwise remove heat from the fins 122.

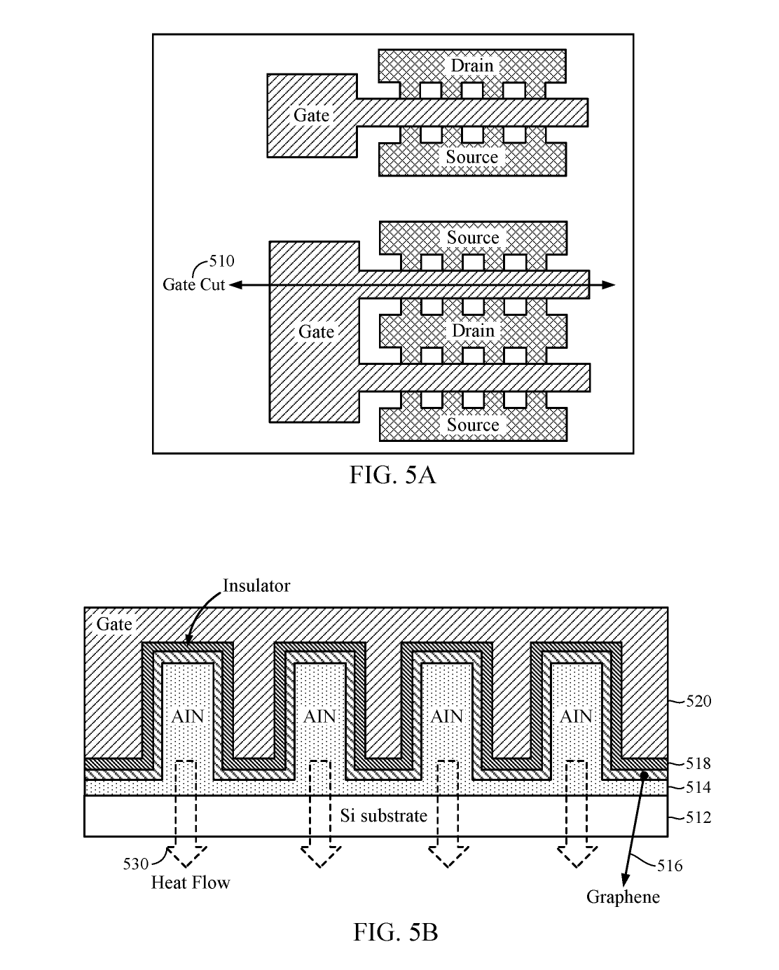

For example, according to various aspects, FIG. 5A shows an exemplary gate cut 510 to produce a horizontal thermal-aware FinFET layout, as shown in FIG. 5B. In particular, as shown in FIG. 5B, an aluminum nitride (AlN) layer 514 can be formed on a silicon substrate 512 (e.g., through epitaxial growth) and the aluminum nitride (AlN) layer 514 may then be etched or otherwise patterned to form the fins from AlN. In various embodiments, a graphene layer 516 can then be formed on the AlN layer 514 (including the AlN fins) and an insulator layer 518 (e.g., a buffer layer and a high-k dielectric) may be formed over the graphene layer 516. A gate metal 520 may then be deposited on the insulator layer 518 to form the thermal-aware FinFET layout shown in FIG. 5B, wherein the graphene layer 516 substantially surrounds the AlN layer 514 and extends through the gate stack to form a graphene channel substantially surrounding the AlN fins in the channel region. As such, because AlN has a high thermal conductivity (˜285 W/mK), using AlN as the fin material and providing the AlN layer 512 over the entire top surface of the substrate 512 may cause heat to flow from the AlN fins to the substrate 512, as depicted at 530. Furthermore, graphene also has a high thermal conductivity (˜500-2000 W/mK), whereby the graphene layer 516 disposed between the AlN layer 514 and the insulator layer 518 may also play an important role to spread heat and decrease hot spot temperatures. Accordingly, whereas a conventional FinFET has fins formed from silicon (Si), which has a thermal conductivity around 5-20 W/mK, using AlN (which has a thermal conductivity around 285 W/mK) as the material in the fins may advantageously result in faster phonon and heat transport to the substrate 512. Furthermore, whereas a conventional FinFET has a source and drain formed from Si, silicon carbide (SiC), silicon-germanium (SiGe), and/or other silicon-based materials that typically have a thermal conductivity around 50 W/mK, using graphene with a thermal conductivity around 500-2500 W/mK in the source and drain stacks may advantageously result in faster heat spreading from high to low temperatures.

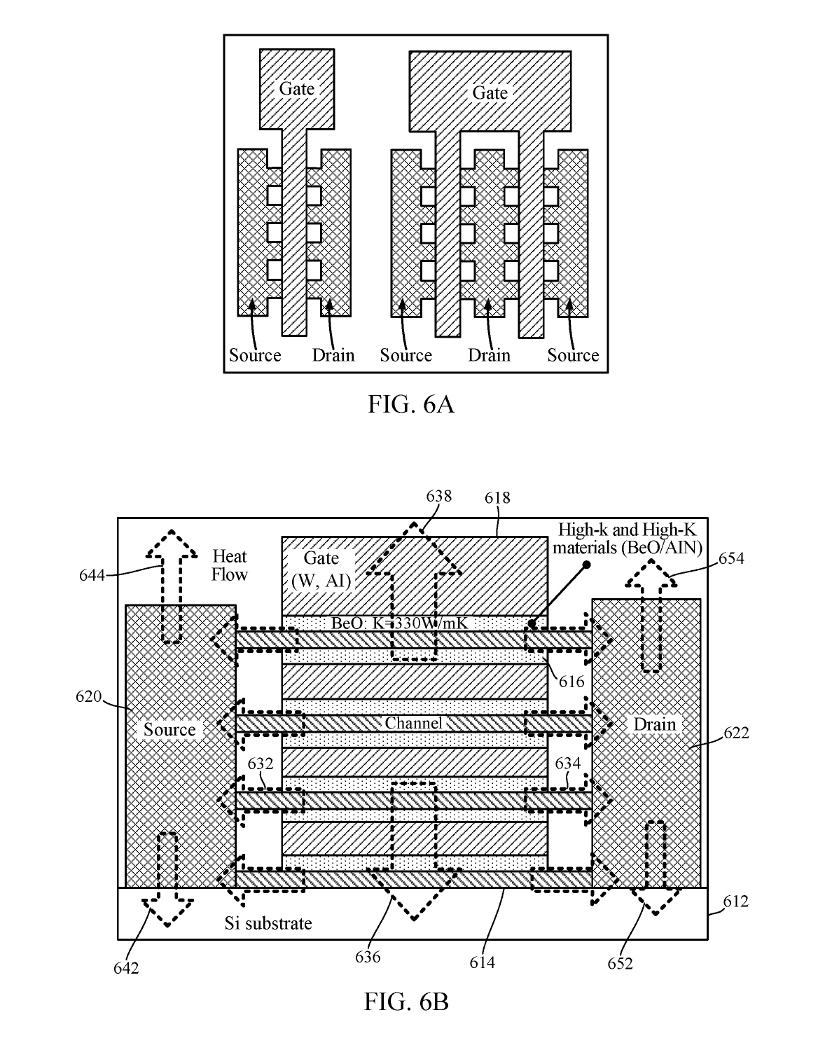

According to various aspects, FIG. 6A and FIG. 6B illustrate an exemplary vertical FET with multiple fingers that may be formed based on the FinFET layouts shown in FIG. 4A-4B. For example, the horizontal thermal-aware FinFET layout shown in FIG. 5B may generally be based on a top-down view of the layouts shown in FIG. 4A-4B. However, in FIG. 6A, the FinFET layouts shown in FIG. 4A-4B are rotated to depict the FinFET layouts according to a cross-sectional view. Accordingly, the multi-finger vertical FET shown in FIG. 6B may comprise a thermal-aware and layered three-dimensional (3D) device, where the fins in the FinFET layouts essentially form a multi-finger channel structure 614 between the source 610 and the drain 622, wherein the source 610 and drain 622 are formed on a Si substrate and the multi-finger channel structure 614 comprises a lower-most finger formed on the Si substrate 612. In various embodiments, the gate stack in the multi-finger vertical FET may include various layers 616 formed from thermal-efficient materials to surround each finger in the channel structure 614 and a gate metal 618 disposed on the top-most layer 616 and between the layers 616 disposed thereunder in the regions disposed between the fingers in the channel structure 614. For example, in various embodiments, the thermal-efficient materials used to form the layers 616 may comprise a high-k dielectric (e.g., hafnium silicate, zirconium silicate, hafnium dioxide, zirconium dioxide, etc.) and other materials having a high thermal conductivity (e.g., aluminum nitride (AlN), beryllium oxide (BeO) with a thermal conductivity at ˜330 W/mK, etc.). Furthermore, in various embodiments, the multi-finger channel structures 614 may be formed from materials with a lattice structure matched to the materials used in the thermal-efficient layers 616.

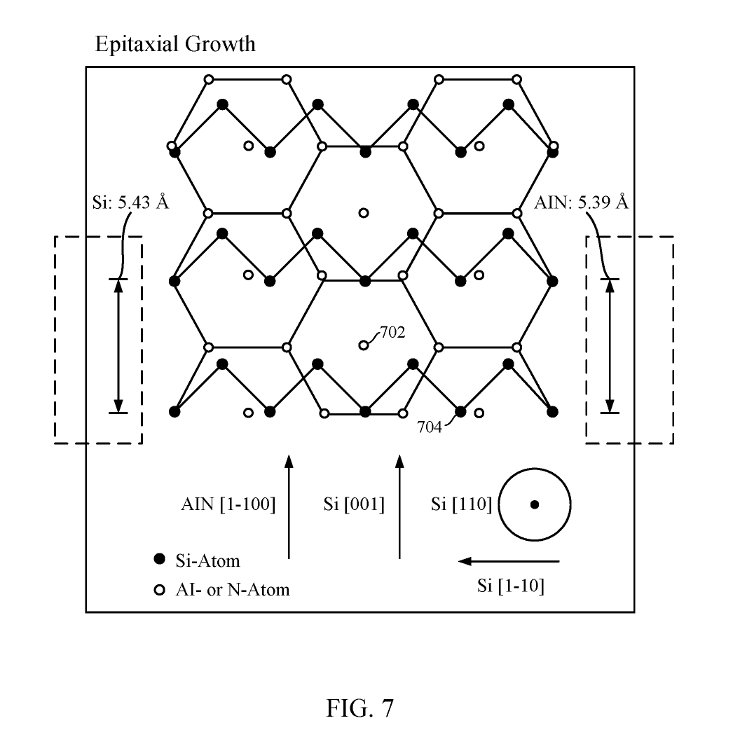

For example, referring to FIG. 7, exemplary atomic structures that can be used to form the thermal-efficient layers 616 through epitaxial growth are shown. In particular, the solid dots exemplified by depicted element 704 may represent atoms associated with the material to be used in the multi-finger channel structures 614, which may comprise silicon atoms in the depicted example. Furthermore, the open dots exemplified by depicted element 702 may represent atoms associated with the material to be used in the thermal-efficient layers 616, which may comprise aluminum or nitrogen atoms in the depicted example (e.g., where AlN is the material used in the thermal-efficient layers 616). Accordingly, because using epitaxial growth to form the thermal-efficient layers 616 on the channel structures 614 (and vice versa) may require the material used in the thermal-efficient layers 616 and the material used in the channel structures 614 to have a well-defined orientation with respect to one another, the materials to be used in the multi-finger channel structures 614 may be chosen based on having a lattice structure matched to the materials used in the thermal-efficient layers 616. For example, FIG. 7 shows that Si has a 5.43 Å lattice constant, which generally refers to the physical dimension that unit cells have in a crystal lattice structure, while AlN has a 5.39 Å lattice constant. As such, in epitaxial growth, the lattice constant may measure the structural similarity between different materials, which has substantial importance with respect to growing one material on another in thin layers because strains can be introduced and thicker layers cannot be grown without defects when the lattice constants differ.

Accordingly, referring back to FIG. 6, the possible materials to use in the thermal-efficient layers 616 may generally include AlN, BeO, and/or other suitable materials that have a sufficiently high thermal conductivity and a lattice structure that can be matched to the materials used in the channel structures 614. Furthermore, due to the need to match the lattices between the materials used in the thermal-efficient layers 616 and the channel structures 614, possible candidate materials to be used in the channel structures 614 may comprise silicon (Si), indium gallium arsenide (InGaAs), silicon-germanium (SiGe), and/or III-V nitrides. As a result, using high-k dielectrics and other thermal-efficient materials in the thermal-efficient layers 616 may provide an efficient heat exit through causing heat to flow down into the substrate 612 and to the gate metal 618 disposed on top of the gate stack, which may be formed from tungsten (W), aluminum (Al), and/or any other suitable metal, as depicted at 636 and 638. Further, materials with high thermal-conductivities may be used in the source stack 620 and the drain stack 622, which may further assist in spreading heat from the channel structures 614, as depicted at 632 and 634 where heat is spread from the channel structures 614 into the source stack 620 and the drain stack 622. Furthermore, the materials used in the source stack 620 and the drain stack 622 continue to spread and remove heat, which exits down into the substrate 612 and upwards to the metal disposed at the top of the source stack 620 and the drain stack 622, as depicted at 642, 644, 652, and 654. For example, in various embodiments, the materials used in the source stack 620 and the drain stack 622 may comprise silicon, silicon-germanium (SiGe), III-V nitrides, graphene, titanium (Ti), titanium nitride (TiN), tungsten (W), etc.

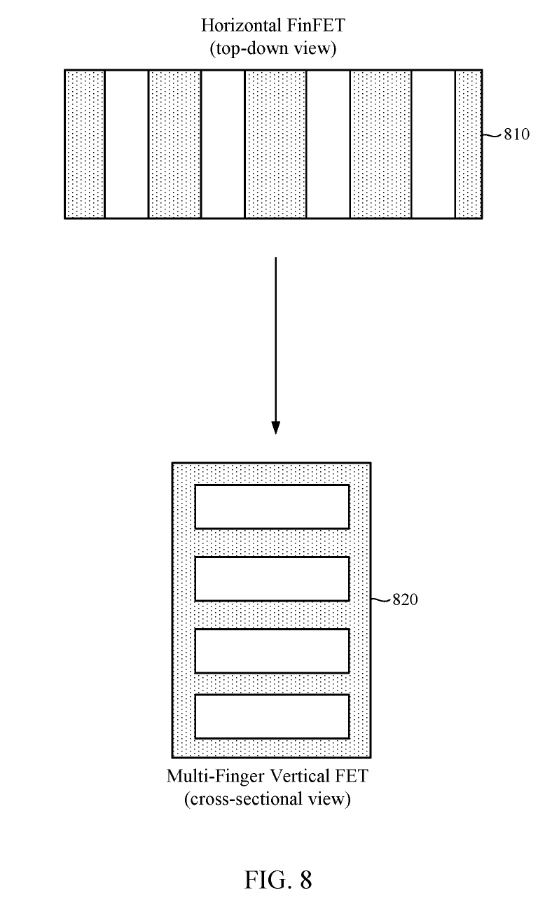

According to various aspects, FIG. 8 illustrates an exemplary comparison between a horizontal FinFET 810 and a multi-finger vertical FET 820 that may each have a thermal-aware FinFET design. For example, as mentioned above, the horizontal FinFET 810 may include fins formed from aluminum nitride (AlN), which has a high thermal conductivity and can therefore provide a main thermal exit from the horizontal FinFET 810. Furthermore, graphene may be used in a source, drain, and channel in the horizontal FinFET 810, where graphene also has a high thermal conductivity and can therefore assist with spreading heat to reduce hot spot temperature. In the multi-finger vertical FET 820, AlN (or BeO or another suitable material with a high thermal conductivity) may also be used in thermal-efficient layers that surround the layers that otherwise form the fins in the horizontal FinFET 810, which instead form channel structures formed from materials with a lattice matched to the materials used in the thermal-efficient layers in the multi-finger vertical FET 820. Furthermore, the multi-finger vertical FET 820 may offer an area reduction over the horizontal FinFET 810.

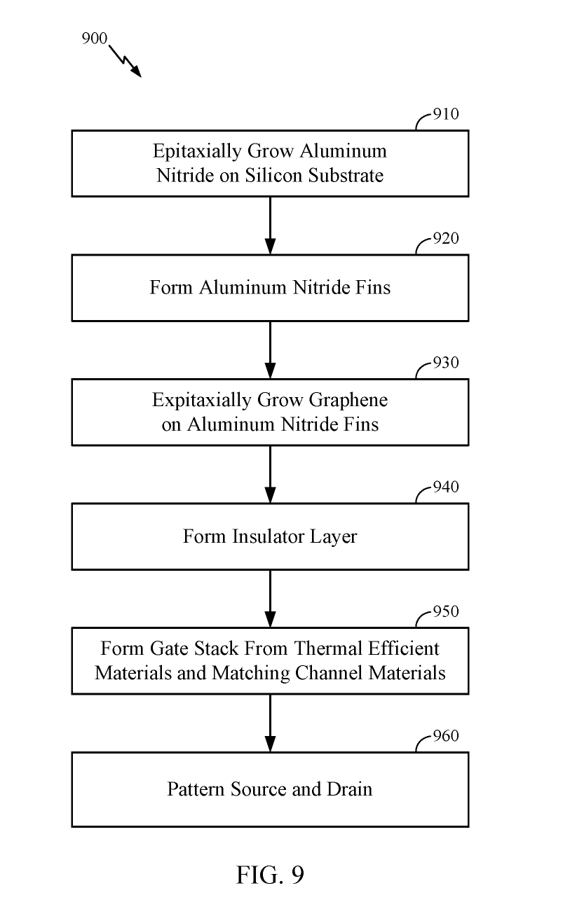

According to various aspects, FIG. 9 illustrates an exemplary method 900 to form a horizontal FinFET and/or a multi-finger vertical FET based on the thermal-aware FinFET design described herein. In particular, according to various embodiments, both the horizontal FinFET and the multi-finger vertical FET may have a design based on a horizontal thermal-aware FinFET layout, whereby block 910 may comprise forming an aluminum nitride (AlN) layer on a silicon substrate through epitaxial growth. The AlN layer may then be etched or otherwise patterned at block 920 to form the fins from AlN. In various embodiments, at block 930, a graphene layer may then be formed on the AlN layer (including the AlN fins) through epitaxial growth and an insulator layer may be formed over the graphene layer at block 940, thereby substantially resulting in the thermal-aware FinFET layout shown in FIG. 5B. According to various aspects, to form the multi-finger vertical FET, the FinFET having the layout resulting from blocks 910 through 940 may be rotated to form a thermal-aware and layered three-dimensional (3D) device, where the fins in the FinFET layout essentially form a multi-finger channel structure. Accordingly, at block 950, a gate stack may be formed from thermal efficient materials and matching channel materials. For example, in various embodiments, the gate stack in the multi-finger vertical FET may include various layers formed from the thermal-efficient materials to surround each finger in the channel structure and a gate metal disposed on the top-most layer and between the layers disposed thereunder (i.e., in the regions disposed between the fingers). For example, in various embodiments, the thermal-efficient materials may comprise high-k dielectrics (e.g., hafnium silicate, zirconium silicate, hafnium dioxide, zirconium dioxide, etc.) and other materials having a high thermal conductivity (e.g., aluminum nitride (AlN), beryllium oxide (BeO) with a thermal conductivity at ˜330 W/mK, etc.). Furthermore, in various embodiments, the matching channel materials may comprise materials with a lattice structure matched to the materials used in the thermal-efficient layers to allow the thermal-efficient layers and the matching channel materials to be formed on one another in a substantially interleaved manner through epitaxial growth. For example, as described in further detail above with respect to FIG. 7, using epitaxial growth to form the thermal-efficient layers on the channel structures (and vice versa) may generally require that the materials used in the thermal-efficient layers and the channel structures have a well-defined orientation with respect to one another.

Accordingly, in various embodiments, the thermal efficient materials used in the gate stack may include AlN, BeO, and/or other suitable materials that have a sufficiently high thermal conductivity and a lattice structure that can be matched to the channel materials, whereby possible candidate channel materials may comprise silicon (Si), indium gallium arsenide (InGaAs), silicon-germanium (SiGe), and/or III-V nitrides. As a result, using high-k dielectrics and other thermal-efficient materials in the thermal-efficient layers may provide an efficient heat exit through causing heat to flow down into the substrate and to the gate metal disposed on top of the gate stack, which may be formed from tungsten (W), aluminum (Al), and/or any other suitable metal. Furthermore, at block 960, the source and drain may be patterned at least in part using materials with high thermal-conductivities, which may further assist in spreading heat from the channel structures. The materials used in the source stack and the drain stack may therefore continue to spread and remove heat, which exits down into the substrate and upward to the metal disposed at the top of the source stack and the drain stack.

According to various aspects, the thermal-aware FinFET design(s) described herein may be provided in, integrated into, or otherwise implemented in any suitable integrated circuit and/or processor-based device that has one or more integrated circuits that implement the horizontal FinFET, the multi-finger vertical FET, and/or any other suitable device based on the thermal-aware FinFET design(s) described herein. For example, in various embodiments, integrated circuits and/or processor-based devices that can include the thermal-aware FinFET design(s) may include, without limitation, a microprocessor-based integrated circuit, system, or other suitable electronic device(s). For example, processor-based electronic devices that can include or otherwise employ the thermal-aware FinFET design(s) described herein can comprise mobile phones, cellular phones, computers, portable computers, desktop computers, personal digital assistants (PDAs), monitors, computer monitors, televisions, tuners, radios, satellite radios, digital music players, portable music players, digital video players, digital video disc (DVD) players, portable digital video players, or the like.

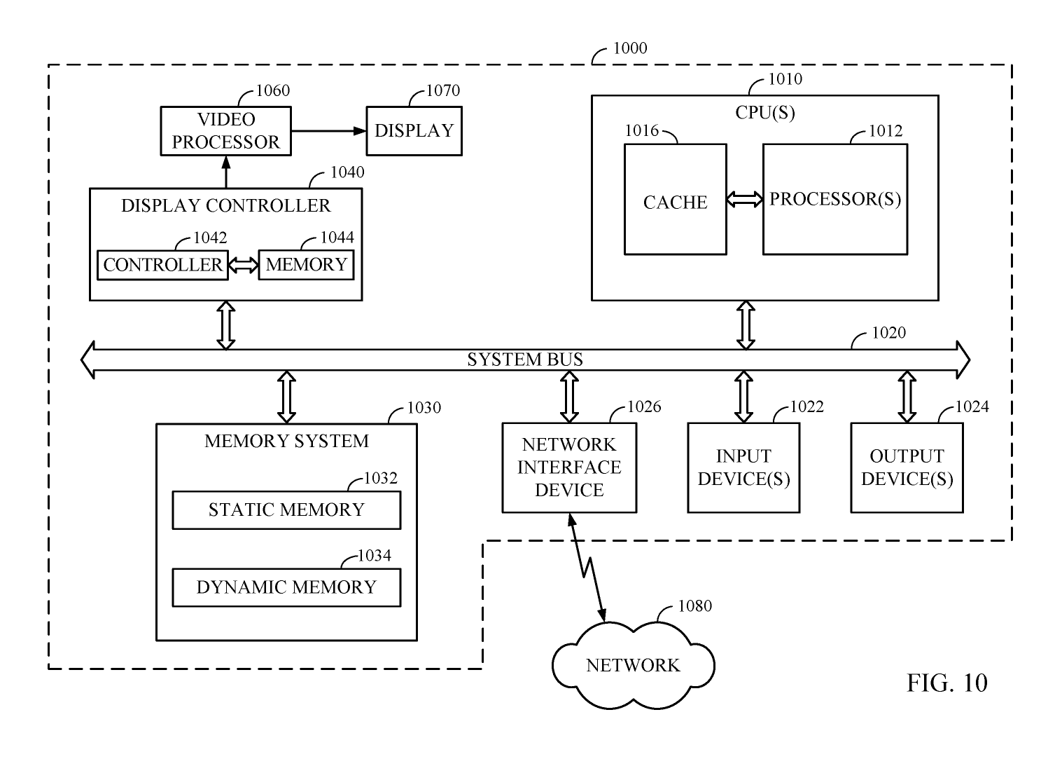

For example, according to various aspects, FIG. 10 illustrates an example processor-based system 1000 that may have one or more integrated circuits implementing the thermal-aware FinFET design(s) described in further detail above. In various embodiments, the processor-based system 1000 may include one or more central processing units (CPUs) 1010, which may each include one or more processors 1012. The CPU(s) 1010 may have a cache memory 1016 coupled to the processor(s) 1012 to rapidly access temporarily stored data. The CPU(s) 1010 can be further coupled to a system bus 1020, which can intercouple various master devices and slave devices included in the processor-based system 1000. Furthermore, as would be apparent to those skilled in the art, the CPU(s) 1010 may exchange address, control, and data information over the system bus 1020 to communicate with these other devices. For example, the CPU(s) 1010 can communicate bus transaction requests to a memory system 1030. Although not explicitly illustrated in FIG. 10, multiple system buses 1020 could be provided, wherein each system bus 1020 may constitute a different fabric.

According to various aspects, other devices can also be connected to the system bus 1020. For example, as illustrated in FIG. 10, the devices connected to the system bus 1020 can include the memory system 1030, one or more input devices 1022, one or more output devices 1024, one or more network interface devices 1026, and one or more display controllers 1040, as examples. The input device(s) 1022 can include any type of input device, including but not limited to input keys, switches, voice processors, etc. The output device(s) 1024 can include any type of output device, including but not limited to audio, video, other visual indicators, etc. The network interface device(s) 1026 can be any devices configured to allow exchange of data to and from a network 1080. The network 1080 can be any type of network, including but not limited to a wired or wireless network, private or public network, a local area network (LAN), a wide local area network (WLAN), and the Internet. The network interface device(s) 1026 can be configured to support any type of communication protocol desired. The memory system 1030 can include static memory 1032 and/or dynamic memory 1034.

According to various aspects, the CPU(s) 1010 may also be configured to access the display controller(s) 1040 over the system bus 1020 to control information sent to one or more displays 1070. The display controller 1040 can include a memory controller 1042 and a memory 1044 to store data to be sent to the display(s) 1070 in response to communications with the CPU(s) 1010. As such, the display controller(s) 1040 may send information to the display(s) 1070 to be displayed via one or more video processors 1060, which may process the information to be displayed into a format suitable for the display(s) 1070. The display(s) 1070 can include any type of display, including but not limited to a cathode ray tube (CRT), a liquid crystal display (LCD), a plasma display, etc.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those skilled in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted to depart from the scope of the various aspects and embodiments described herein.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, etc.).

The methods, sequences and/or algorithms described in connection with the aspects disclosed herein may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an IoT device. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, DSL, or wireless technologies such as infrared, radio, and microwave, then the coaxial cable, fiber optic cable, twisted pair, DSL, or wireless technologies such as infrared, radio, and microwave are included in the definition of a medium. The term disk and disc, which may be used interchangeably herein, includes CD, laser disc, optical disc, DVD, floppy disk, and Blu-ray discs, which usually reproduce data magnetically and/or optically with lasers. Combinations of the above should also be included within the scope of computer-readable media.

While the foregoing disclosure shows illustrative aspects and embodiments, those skilled in the art will appreciate that various changes and modifications could be made herein without departing from the scope of the disclosure as defined by the appended claims. Furthermore, in accordance with the various illustrative aspects and embodiments described herein, those skilled in the art will appreciate that the functions, steps and/or actions in any methods described above and/or recited in any method claims appended hereto need not be performed in any particular order. Further still, to the extent that any elements are described above or recited in the appended claims in a singular form, those skilled in the art will appreciate that singular form(s) contemplate the plural as well unless limitation to the singular form(s) is explicitly stated.

1. A thermal-aware finned field-effect transistor (FinFET), comprising:
a source stack formed on a substrate;
a drain stack formed on the substrate; and
a gate stack formed on the substrate in a channel region disposed between the source stack and the drain stack, wherein the gate stack comprises:
multiple channel structures intersecting the source stack and the drain stack, wherein the multiple channel structures comprise a lower-most channel structure formed on the substrate; and
thermal-efficient layers formed around the multiple channel structures, wherein the thermal-efficient layers are formed from a high-k dielectric material and a material having a high thermal conductivity.

2. The thermal-aware FinFET recited in claim 1, wherein the multiple channel structures are formed from a material having a lattice matched to the material in the thermal-efficient layers having the high thermal conductivity.

3. The thermal-aware FinFET recited in claim 2, wherein the thermal-efficient layers comprise a first layer formed on the lower-most channel structure through epitaxial growth and at least one second layer having one of the multiple channel structures formed thereon through epitaxial growth.

4. The thermal-aware FinFET recited in claim 2, wherein the material in the thermal-efficient layers having the high thermal conductivity comprises one or more of aluminum nitride or beryllium oxide.

5. The thermal-aware FinFET recited in claim 4, wherein the material used in the multiple channel structures with the matching lattice comprises one or more of silicon, indium gallium arsenide, silicon-germanium, or a III-V nitride.

6. The thermal-aware FinFET recited in claim 1, wherein the material having the high thermal conductivity causes heat to flow downward into the substrate and upward to a metal gate formed atop the gate stack.

7. The thermal-aware FinFET recited in claim 6, wherein the multiple channel structures intersecting the source stack and the drain stack spread heat from the gate stack into the source stack and the drain stack.

8. The thermal-aware FinFET recited in claim 7, wherein the source stack and the drain stack are formed from a material that causes the heat to further flow downward into the substrate and upward through the source stack and the drain stack.

9. A method for forming a finned field-effect transistor (FinFET), comprising:
forming a source stack and a drain stack on a substrate; and
forming a gate stack on the substrate in a channel region disposed between the source stack and the drain stack, wherein forming the gate stack comprises:
forming multiple channel structures that intersect the source stack and the drain stack, wherein the multiple channel structures comprise a lower-most channel structure formed on the substrate; and
forming thermal-efficient layers around the multiple channel structures from a high-k dielectric material and a material having a high thermal conductivity.

10. The method recited in claim 9, wherein the multiple channel structures are formed from a material having a lattice matched to the material in the thermal-efficient layers having the high thermal conductivity.

11. The method recited in claim 10, wherein the thermal-efficient layers comprise a first layer formed on the lower-most channel structure through epitaxial growth and at least one second layer having one of the multiple channel structures formed thereon through epitaxial growth.

12. The method recited in claim 10, wherein the material in the thermal-efficient layers having the high thermal conductivity comprises one or more of aluminum nitride or beryllium oxide.

13. The method recited in claim 12, wherein the material used in the multiple channel structures with the matching lattice comprises one or more of silicon, indium gallium arsenide, silicon-germanium, or a III-V nitride.

14. The method recited in claim 9, wherein the material having the high thermal conductivity causes heat to flow downward into the substrate and upward to a metal gate formed atop the gate stack.

15. The method recited in claim 14, wherein the multiple channel structures that intersect the source stack and the drain stack spread heat from the gate stack into the source stack and the drain stack.

16. The method recited in claim 15, wherein the source stack and the drain stack are formed from a material that causes the heat to further flow downward into the substrate and upward through the source stack and the drain stack.

17. A thermal-aware finned field-effect transistor (FinFET), comprising:
a substrate;
a source stack and a drain stack formed on the substrate, wherein the source stack and the drain stack each comprise an aluminum nitride layer formed on the substrate and a graphene layer formed over the aluminum nitride layer; and
a gate stack formed on the substrate, wherein the gate stack comprises:
one or more fin-shaped structures formed from aluminum nitride in a channel region between the source stack and the drain stack; and
a graphene channel formed over the fin-shaped structures.

18. The thermal-aware FinFET recited in claim 17, wherein the aluminum nitride layer and the one or more fin-shaped structures formed from aluminum nitride cause heat to flow downward into the substrate.

19. The thermal-aware FinFET recited in claim 17, wherein the graphene layer substantially surrounds the aluminum nitride layer and extends through the gate stack to form the graphene channel such that the graphene channel substantially surrounds the fin-shaped structures formed from the aluminum nitride in the channel region.

20. The thermal-aware FinFET recited in claim 19, wherein the graphene layer and the graphene channel spread heat throughout the thermal-aware FinFET.

21. The thermal-aware FinFET recited in claim 17, wherein the gate stack further comprises an insulator layer formed over the graphene channel and a metal gate formed over the insulator layer.

22. A method for forming a finned field-effect transistor (FinFET), comprising:
forming a source stack and a drain stack on a substrate, wherein the source stack and the drain stack each comprise an aluminum nitride layer formed on the substrate and a graphene layer formed over the aluminum nitride layer; and
forming a gate stack on the substrate, wherein forming the gate stack comprises:
forming one or more fin-shaped structures from aluminum nitride in a channel region between the source stack and the drain stack; and
forming a graphene channel over the fin-shaped structures.

23. The method recited in claim 22, wherein the aluminum nitride layer and the one or more fin-shaped structures formed from aluminum nitride cause heat to flow downward into the substrate.

24. The method recited in claim 22, wherein the graphene layer substantially surrounds the aluminum nitride layer and extends through the gate stack to form the graphene channel such that the graphene channel substantially surrounds the fin-shaped structures formed from the aluminum nitride in the channel region.

25. The method recited in claim 24, wherein the graphene layer and the graphene channel spread heat throughout the thermal-aware FinFET.

26. The method recited in claim 22, wherein forming the gate stack further comprises:
forming an insulator layer over the graphene channel; and
forming a metal gate over the insulator layer.
